(19) United States
(12) Patent Application Publication
(10) Pub. No.: US 2011/0198628 A1
(43) Pub. Date: Aug. 18, 2011

(54) MULTI-CHIP LED PACKAGE

(75) Inventor: Duk-Yong Kim, Gyeonggi-do (KR)

(73) Assignee: K.M.W. INC., Hwasung-si, Gyeonggi-do (KR)

(21) Appl. No.: 13/124,154

(22) PCT Filed: Oct. 21, 2009
(86) PCT No.: PCT/KR2009/006090

§ 371 Date: Apr. 14, 2011

(30) Foreign Application Priority Data
Oct. 21, 2008 (KR) 10-2008-0103333
Oct. 23, 2008 (KR) 10-2008-0104135
Nov. 14, 2008 (KR) 10-2008-0113575

(51) Int. Cl. H01L 27/15

(52) U.S. Cl. 257/88; 257/E27.12

(57) ABSTRACT

A multichip light-emitting-diode (LED) package includes a printed circuit board (PCB) having a tapered via hole and a circuit interconnection line on a surface of the PCB. An inclined surface of each via hole is used as a reflection plate reflecting light emitted by an LED chip located in the via hole. Each LED chip is directly bonded to a metal base for radiating heat. Additional heat radiation structures and reflection plates are not required, thus simplifying the structure of and manufacture of the multichip LED package, reducing manufacturing costs.

### TECHNICAL FIELD

The present invention relates to a multichip light-emitting-diode (LED) package, and more particularly, to a multichip LED package that does not require an additional reflection plate or heat radiation structure.

### BACKGROUND ART

In general, a light emitting diode (hereinafter referred to as an “LED”), which is a device configured to generate light due to application of current, enables continuous emission of light at a low voltage and with a small current and has low power consumption, compared to conventional light sources. Owing to the above-described merits, LEDs are lately being applied more broadly in fields of illumination systems using LEDs and backlight units (BLUs) of flat panel display (FPD) devices.

Methods of fabricating LEDs may be largely classified into a method of mixing light of discrete devices configured to respectively generate red (R), green (G), and blue (B) light and packaging the discrete devices onto a substrate to allow an illumination system or BLU to generate white light and a method of bonding a single LED chip including R, G, and B LEDs to a substrate and packaging the LED chip onto the substrate using a wire bonding technique. A conventional LED package will now be described in detail with reference to FIG. 1.

FIG. 1 is a cross-sectional view of a conventional LED package.

Referring to FIG. 1, the conventional LED package includes a metal base 1, an insulating layer 2 deposited on the entire top surface of the metal base 1, LED chips 3 adhered to a portion of a top surface of the insulating layer 2, an interconnection layer 4 disposed on the insulating layer 2 and configured to supply power to each of the LED chips 3, a wire 5 configured to connect the interconnection layer 4 to each of the LED chips 3, a reflection plate 6 spaced a predetermined distance apart from each of the LED chips 3 and disposed on the interconnection layer 4 and the insulating layer 2, an encapsulant (epoxy molding compound (EMC)) 7 disposed on portions of top surfaces of the LED chips 3 in a space formed by the reflection plates 6, a diffusing agent 8 disposed from a top surface of the encapsulant 7 to the height of the reflection plate 6, and a lens 9 disposed on the entire top surface of the resultant structure.

Hereinafter, a construction of the conventional LED package having the above-described construction and a method of fabricating the same will be described in further detail.

To begin with, an insulating layer 2 is deposited on a metal base 1, and a metal interconnection material is deposited on the entire top surface of the insulating layer 3 and etched using photolithography, thereby forming an interconnection layer 4.

In this case, interconnection layers 4 may be spaced apart from one another to ensure spaces where LED chips 3 may be mounted.

Next, the LED chips 3 are disposed between the interconnection layers 4 and adhered onto the insulating layer 2. In this case, the adhesion of the LED chips 3 to the insulating layer 2 may be performed using an adhesive. Thereafter, wires 5 may be bonded to each of the interconnection layers 4 and each of the LED chips 3 so that power can be supplied to each of the LED chips 3.

Next, reflection plates 6 formed of an inorganic or organic material capable of diffusing light are prepared, via holes are formed in the reflective plates 6 to expose portions corresponding to the LED chips 3 and the wires 5, and the reflection plates 6 are bonded to the insulating layer 2 and the interconnection layers 4 to expose the LED chips 3 and the wires 5.

In this case, the via holes formed in the reflection plates 6 are formed to have vertical lateral portions. Next, the via holes of the reflection plates 6 are filled with an encapsulant 7, which is an epoxy resin or silicon resin. In this case, the encapsulant 7 is filled to a height equal to or greater than the height of the LED chips 3 not to reach the height of the reflection plates 6. Afterwards, a diffusing agent 9 formed of an inorganic or organic material capable of diffusing light is formed on the encapsulant 7. The diffusing agent 8 may be configured to have the same height as the reflection plates 6. Next, a lens 9 is bonded to the entire top surfaces of the reflection plates 6 and the diffusing plate 6.

Since the conventional multichip LED package having the above-described construction needs to have additional reflection plates 6 to diffuse generated light, the configuration and manufacture of the conventional multichip LED package are relatively complicated, thus increasing manufacturing costs and reducing yield. Also, although the metal base 1 is used to radiate heat, the metal base 1 and the LED chips 3 are interposed between the insulating layers 2, degrading heat radiation efficiency. Thus, when the conventional multichip LED package is used for an illumination apparatus, an additional heat radiation structure is required.

In addition, there is a technical limit to reducing a distance between the LED chips 3 due to the use of the reflection plate 6, thus precluding manufacture of a small-sized high-output illumination apparatus.

### SUMMARY OF THE INVENTION

The present invention provides a multichip light-emitting-diode (LED) package capable of sufficiently reflecting and emitting light without using an additional reflection plate.

The present invention also provides a multichip LED package in which an LED chip is directly bonded to a metal base to enable effective radiation of heat generated by the LED chip.

Furthermore, the present invention provides a multichip LED package that minimizes a distance between LED chips to increase the integration density of the LED chips.

According to an exemplary embodiment, a multichip LED package is disclosed. The multichip LED package includes a printed circuit board (PCB) including a tapered via hole. An inclined surface of the via hole is used as a reflection plate configured to reflect light emitted by an LED chip.

In addition, a plurality of via holes and a plurality of LED chips may be formed, and each of the LED chips may be directly bonded to a metal base serving as a heat radiating plate.

According to the present invention, an LED chip is directly bonded onto a metal base capable of easily radiating heat, and an inclined surface of a via hole of a printed circuit board (PCB) is plated with a metal and used as a reflection plate. Thus, since an additional reflection plate is not required, configuration and manufacture of a multichip LED package are simplified, thus reducing manufacturing costs.

In addition, no reflection plate is used between LED chips so that a distance between the LED chips can be minimized to increase integration density. Due to an increase in the integration density, a high-output illumination apparatus can be provided.

Furthermore, by directly bonding an LED chip to a metal base, heat generated by the LED chip can be effectively radiated.

### BRIEF DESCRIPTION OF DRAWINGS

FIG. 1 is a cross-sectional view of a conventional light-emitting diode (LED) package.

FIG. 2 is a cross-sectional view of a single pixel portion of a multichip LED package according to an exemplary embodiment of the present invention.

FIG. 3 is a cross-sectional view of a plurality of pixel portions of a multichip LED package according to an exemplary embodiment of the present invention.

FIG. 4 is an exploded perspective view of a multichip LED package according to an exemplary embodiment of the present invention.

FIG. 5 is a plan view of a printed circuit board (PCB) according to an exemplary embodiment of the present invention.

FIG. 6 is a cross-sectional view of a single pixel portion of a multichip LED package according to another exemplary embodiment of the present invention.

FIG. 7 is a plan view of a PCB according to another exemplary embodiment of the present invention.

FIG. 8 is a cross-sectional view of a single pixel portion of a multichip LED package using a multilayered PCB, according to another exemplary embodiment of the present invention.

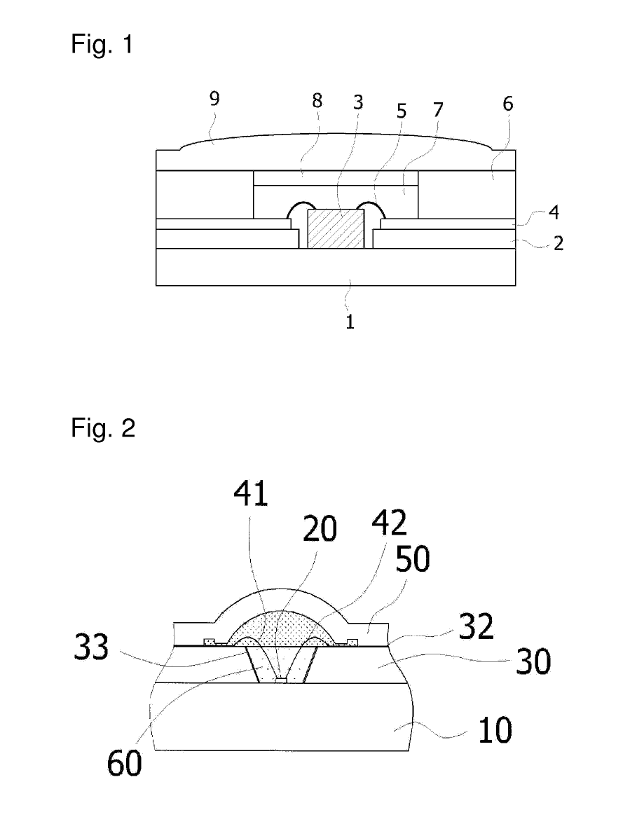

### DETAILED DESCRIPTION

Hereinafter, exemplary embodiments of the present invention will be described in detail with reference to the accompanying drawings.

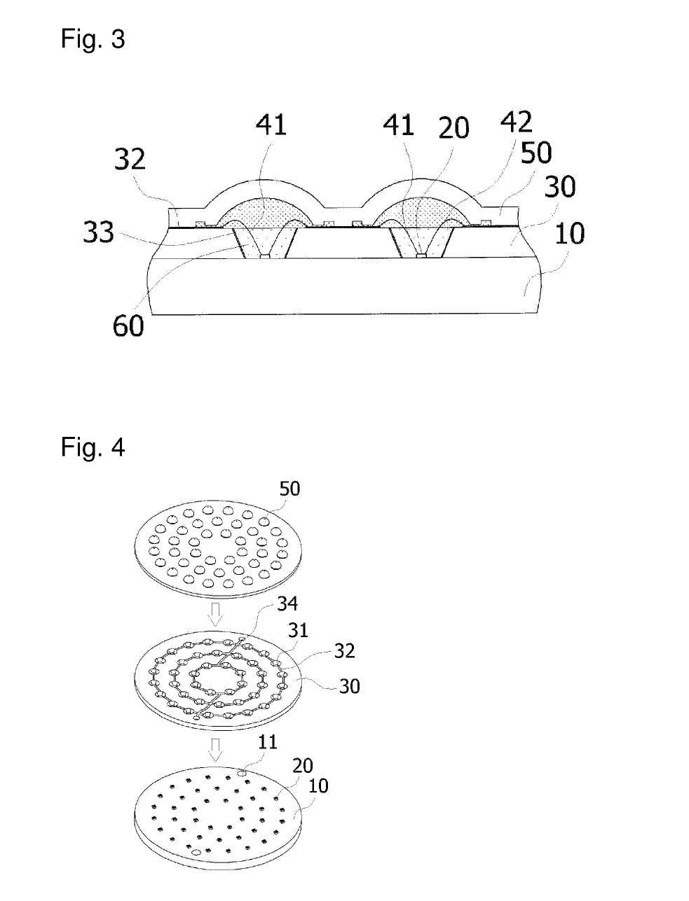

FIG. 2 is a cross-sectional view of a single pixel portion of a multichip LED package according to an exemplary embodiment of the present invention, FIG. 3 is a cross-sectional view of a plurality of pixel portions of a multichip LED package according to an exemplary embodiment of the present invention, and FIG. 4 is an exploded perspective view of a multichip LED package according to an exemplary embodiment of the present invention.

Referring to FIGS. 2 through 4, the multichip LED package according to the exemplary embodiment of the present invention includes a plurality of LED chips 20 adhered onto a metal base 10 configured to radiate heat, a printed circuit board (PCB) 30 including tapered via holes 31 formed in the corresponding positions of the LED chips 20 and a circuit interconnection line 32 disposed on a top surface of the PCB 30 to connect the LED chips 20, first and second wires 41 and 42 configured to connect each of the LED chips 20 and the circuit interconnection line 32, and an optical plate 50 bonded to the entire surface of the PCB 30.

Reference numeral 60 denotes an encapsulant filling the tapered via holes 31, and 33 denotes a metal layer prepared in the via holes 31 and used as reflection plates.

Hereinafter, the above-described multichip LED package according to an exemplary embodiment of the present invention will be described in detail with reference to FIGS. 2 through 4.

To begin with, a metal base 10 may be a heat sink or a metal heat radiating plate, and LED chips 20 are bonded to the metal base 10.

That is, a conventional heat-radiating interconnection substrate is not used.

Although a circular metal base 10 is illustrated in the drawings, a metal base having a polygonal top surface, such as a triangular top surface, a square top surface, or a rectangular top surface, may be used. The shape of the metal base 10 may be arbitrarily changed according to the shape of an illumination apparatus.

In addition, via holes 31 are formed in positions corresponding to the LED chips 20 such that all the LED chips 20 are exposed when the PCB 30 is bonded to the metal base 10.

In this case, the via holes 31 are formed in a tapered shape instead of a conventional cylindrical shape. That is, upper portions of the via holes 31 are wider than lower portions thereof.

Preferably, the PCB 30 has the same size and shape as the metal base 10.

Next, a circuit interconnection line 32 is formed on a top surface of the PCB 30 so as to connect the LED chips 20. In this case, the circuit interconnection line 32 is not connected through the insides of the via holes 31.

Meanwhile, the via holes 31 are used as reflection plates configured to reflect light emitted by the LED chips 20. To increase reflection efficiency, a metal layer 33 may be formed in the via holes 31 using an additional plating process.

The metal layer 33 may be formed of a metal having a high reflectance, such as platinum (Pt), silver (Ag), nickel (Ni), or aluminum (Al).

After the PCB 30 is stacked on the metal base 10, the LED chips 20 and the circuit interconnection line 32 are bonded to each other using first and second wires 41 and 42.

Then, the via holes 31 are filled with an encapsulant 60, and an optical plate 50 including a plurality of lenses are bonded to the PCB 30, thereby completing a packaging process.

In addition, reference numeral 34 denotes an electrode pad configured to supply power to the circuit interconnection line 32. The electrode pad 34 is formed through a portion of the PCB 30 and exposed through a hole 11 prepared in the metal base 10 in a bottom surface thereof. By supplying power to the exposed electrode pad 34, the LED chips 20 may be driven.

The above-described structures of the circuit interconnection line 32 and electrode pad 34 are only exemplary embodiments and may be widely changed by those skilled in the art without departing from the scope of the present invention.

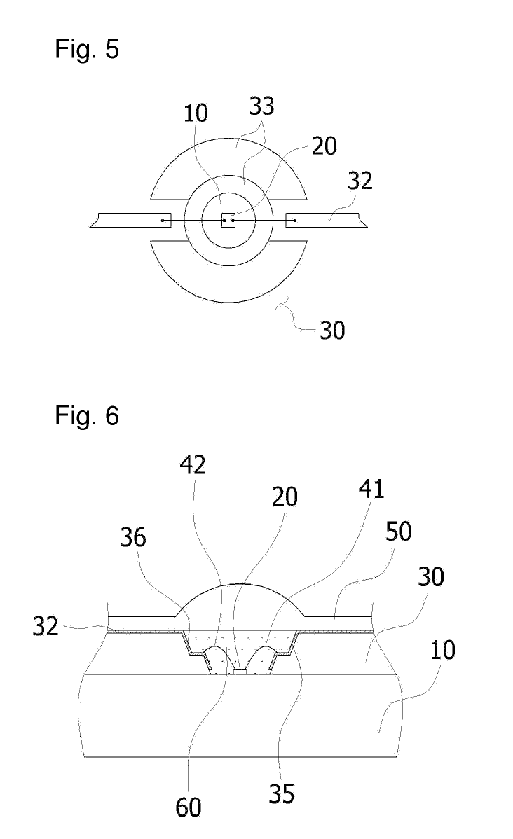

FIG. 5 is a plan view of a portion of the PCB 30, according to an exemplary embodiment of the present invention. The circuit interconnection line 32 and the via hole 31 will now be described in further detail with reference to FIG. 5.

As shown in FIG. 5, the metal layer 33 formed in the via hole 31 is connected to an outer circumferential surface of the via hole 31 formed on the top surface of the PCB 30 to a predetermined length.

The configuration shown in FIG. 5 is provided to increase reflection efficiency when light emitted by the LED chip 20 is reflected by the optical plate 50 and bumped into the top surface of the PCB 30.

FIG. 6 is a cross-sectional view of a single pixel portion of a multichip LED package according to another exemplary embodiment of the present invention.

Referring to FIG. 6, to increase reflection efficiency of light emitted by LED chips 20, via holes 31 are formed to have a plurality of inclined surfaces instead of a single inclined surface.

In this case, a flat portion is provided in an inclined lateral surface of each of the via holes 31 to facilitate a wire bonding process.

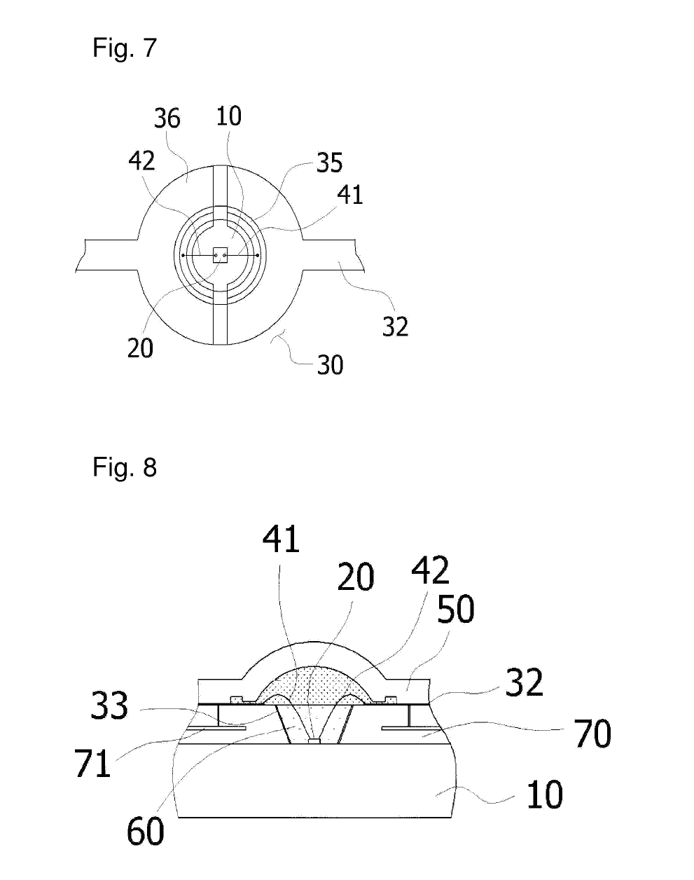

However, since a circuit interconnection line 32 formed on a top surface of a PCB 30 needs to be connected to a metal layer formed in the via hole 31, as can be seen from a plan view of FIG. 7, the metal layer is divided into two portions and first and second reflection plates 35 and 36 are dividedly formed in the portions of the metal layer, respectively, so that the first and second reflection plates 35 and 36 can be electrically isolated from each other.

In addition, lower portions of the first and second reflection plates 35 and 36 are formed not to reach a bottom portion of the via hole 31 and thus not electrically connected to the metal base 10.

Although a single PCB is described as an example of the PCB 30 in the above-described embodiments, a multilayered PCB may be used.

FIG. 8 is a cross-sectional view of a single pixel portion of a multichip LED package using a multilayered PCB 70, according to another exemplary embodiment of the present invention.

Referring to FIG. 8, the multilayered PCB 70 may include a driver circuit portion 71 formed in an intermediate layer. Thus, a thin-type light source may be provided without using an additional external LED driver circuit.

The driving circuit portion 71 may be provided with an interconnection line or any other circuit pattern capable of adjusting a voltage.

A conventional LED illumination system have been manufactured by forming an LED module including an interconnection line capable of supplying power to LED chips and a driver circuit portion configured to drive each of the LED chips of the LED module in a separate PCB and connecting the LED module and the driver circuit portion to each other.

However, a multichip LED package according to the present invention includes a driver circuit portion configured to drive LEDs formed in the same intermediate layer of the PCB as the LED, thus simplifying a manufacturing process and providing a thin-type illumination system.

### INDUSTRIAL APPLICABILITY

An LED chip is directly bonded onto a metal base capable of easily radiating heat, and an inclined surface of a via hole of a printed circuit board (PCB) is plated with a metal and used as a reflection plate. Thus, since an additional reflection plate is not required, configuration and manufacture of a multichip LED package can be simplified, thus reducing manufacturing costs.

While the invention has been shown and described with reference to m certain exemplary embodiments thereof, it will be understood by those skilled in the art that various changes in form and details may be made therein without departing from the spirit and scope of the invention as defined by the appended claims.

1. A multichip light-emitting-diode (LED) package comprising a printed circuit board (PCB) including a tapered via hole, wherein an inclined surface of the via hole reflects light emitted by an LED chip.

2. The package of claim 1, comprising a plurality of via holes in the PCB and a plurality of LED chips.

3. The package of claim 2, including a metal base for radiating heat, wherein the LED chips are bonded to the metal base.

4. The package of claim 3, wherein the PCB is stacked on the metal base.

5. The package of claim 1, further comprising an encapsulant filling the via hole.

6. The package of claim 5, further comprising an optical plate stacked on the PCB, wherein the optical plate includes a lens disposed in a position corresponding to the LED chip.

7. The package of claim 5, including a reflection plate located on the inclined surface of the via hole.

8. The package of claim 1, including a reflection plate on the inclined surface of the via hole.

9. The package of claim 2, wherein the PCB is a multilayered PCB including an intermediate layer, in which a driver circuit portion, for driving the LED chips, is located.

10. A multichip light-emitting diode (LED) package comprising:
a printed circuit board (PCB) including a plurality of tapered via holes having inclined surfaces that are inclined relative to a surface of the PCB; and
a plurality of LED chips mounted within respective via holes so that light emitted by an LED chip is reflected from the inclined surface of the respective via hole.

11. The package of claim 10, including a metal base for radiating heat, wherein the LED chips are bonded to the metal base.

12. The package of claim 11, wherein the PCB is stacked on the metal base.

13. The package of claim 10, further comprising an encapsulant filling the via holes.

14. The package of claim 10, further comprising an optical plate stacked on the PCB, wherein the optical plate includes a plurality of lenses disposed in positions corresponding to respective LED chips.

15. The package of claim 10, including reflection plates located on the inclined surfaces of the via holes.

16. The package of claim 10, wherein the PCB is a multilayered PCB including an intermediate layer, in which a driver circuit portion, for driving the LED chips, is located.
